(19) United States
(12) Patent Application Publication
(10) Pub. No.: US 2018/0166000 A1
(43) Pub. Date: Jun. 14, 2018

(54) ARRAY SUBSTRATE AND MANUFACTURING METHOD THEREOF, DISPLAY PANEL AND DISPLAY DEVICE

(71) Applicant: BOE TECHNOLOGY GROUP CO., LTD., Beijing (CN)

(72) Inventors: Li XIAO, Beijing (CN); Xiaolong HE, Beijing (CN)

(21) Appl. No.: 15/556,507

(22) PCT Filed: Jan. 17, 2017
(86) PCT No.: PCT/CN2017/071415

§ 371 Date: Sep. 7, 2017

(30) Foreign Application Priority Data
May 31, 2016 (CN) 201610378261.6

(51) Int. Cl. G09G 3/14; G02F 1/133; G02F 1/1335; H01L 21/82

(52) U.S. Cl. CPC G09G 3/14; G02F 1/13306; G09G 2310/0243; H01L 21/82; G09G 2330/028; G02F 1/133514

(57) ABSTRACT

An array substrate and a manufacturing method thereof, a display panel and a display device are provided. The array substrate includes: a base substrate; a gate line and a data line disposed on the base substrate, wherein the gate line and the data line are intersected to define a pixel region; and a pixel electrode and a common electrode that are in the pixel region, wherein both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode.

### TECHNICAL FIELD

Embodiments of the present disclosure relate to an array substrate and a manufacturing method thereof, a display panel and a display device.

### BACKGROUND

Thin-film transistor liquid crystal displays (TFT-LCDs) are liquid crystal display (LCD) devices taking thin-film transistors (TFTs) as switching control elements of pixel units. Electrical properties, optical properties and display modes of liquid crystals affect the display effect of the LCD devices directly. In a field of TFT-LCD, the common liquid crystal display modes comprise a twisted nematic (TN) display mode, an in-plane switching (IPS) display mode, an advanced super dimension switch (ADS) display mode, etc.

The IPS display mode has advantages of a large viewing angle, a high dynamic resolution and a good color restoration effect, and the IPS display mode is widely applied in the fields of high technological content such as aerospace, medical treatment and design. In the IPS display mode, two electrodes are disposed in a same plane, and liquid crystal molecules rotate in the plane, so as to achieve brightness control. However, no matter in what state, the liquid crystal molecules are always expected to be parallel to a display panel in the IPS display mode. Uneven arrangement of liquid crystal molecules will reduce aperture ratio and light transmittance of the display panel, and hence reduce the brightness.

### SUMMARY

At least one embodiment of the present disclosure provides an array substrate, and the array substrate comprises: a base substrate; a gate line and a data line which are disposed on the base substrate, wherein the gate line and the data line are intersected to define a pixel region; and a pixel electrode and a common electrode that are in the pixel region; wherein both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode.

For example, in the array substrate provided in at least one embodiment of the present disclosure, both the pixel electrode and the common electrode are made of a conductive resin material.

For example, in the array substrate provided in at least one embodiment of the present disclosure, the conductive resin material may comprise a resin matrix and a conductive dopant.

For example, in the array substrate provided in at least one embodiment of the present disclosure, the resin matrix may comprise epoxy resin, acrylic resin or polyurethane.

For example, in the array substrate provided in at least one embodiment of the present disclosure, the conductive dopant may comprise metal particles, metal fibers, carbon particles, carbon fibers, or graphene.

For example, in the array substrate provided in at least one embodiment of the present disclosure, the array substrate further comprises a thin film transistor (TFT), and the TFT comprises: a gate electrode connected to the gate line, an active layer, a source electrode connected to the data line and in contact with the active layer, a drain electrode arranged opposite to the source electrode and in contact with the active layer, and a gate insulating layer disposed between the gate electrode and the active layer, wherein the drain electrode is further electrically connected with the pixel electrode.

For example, in the array substrate provided in at least one embodiment of the present disclosure, a passivation layer is provided on the TFT and a via hole penetrates the passivation layer.

For example, in the array substrate provided in at least one embodiment of the present disclosure, the pixel region comprises at least one pixel electrode and at least one common electrode.

For example, in the array substrate provided in at least one embodiment of the present disclosure, the TFT may be a bottom-gate TFT or a top-gate TFT.

For example, in the array substrate provided in at least one embodiment of the present disclosure, the pixel electrode and the common electrode are in a shape of strip, and the pixel electrode and the common electrode are arranged opposite to each other.

For example, in the array substrate provided in at least one embodiment of the present disclosure, the pixel region comprises at least one pixel electrode and at least one common electrode.

For example, the array substrate provided in at least one embodiment of the present disclosure may further comprise a common electrode line, wherein the common electrode is electrically connected with the common electrode line.

At least one embodiment of the present disclosure further provides a display panel, and the display panel comprises: any one of the array substrate described above, an opposed substrate arranged in parallel to the base substrate, and liquid crystal molecules disposed between the array substrate and the opposed substrate.

For example, in the display panel provided in at least one embodiment of the present disclosure, both a thickness of the pixel electrode and a thickness of the common electrode in a direction perpendicular to the base substrate are a thickness of the liquid crystal molecules layer.

For example, in the display panel provided in at least one embodiment of the present disclosure, both the pixel electrode and the common electrode are perpendicular to the opposed substrate and configured to support the opposed substrate.

For example, in the display panel provided in at least one embodiment of the present disclosure, the opposed substrate is a color filter (CF) substrate.

At least one embodiment of the present disclosure further provides a display device, and the display device comprises any one of the display panel described above.

At least one embodiment of the present disclosure further provides a method for manufacturing an array substrate, and the method comprises: forming a gate line, a data line and a pixel region defined by the intersection of the gate line and the data line on a base substrate; and forming a pixel electrode and a common electrode in the pixel region, wherein both the pixel electrode and the common electrode are perpendicular to the base substrate and protruded from the base substrate, and the pixel electrode and the common electrode are opposite to each other; an electric field parallel to the base substrate is generated between a surface of the pixel electrode facing the common electrode and a surface of the common electrode facing the pixel electrode.

For example, in the manufacturing method provided in at least one embodiment of the present disclosure, both the pixel electrode and the common electrode are made of a conductive resin material.

For example, in the manufacturing method provided in at least one embodiment of the present disclosure, the conductive resin material comprises a resin matrix and a conductive dopant.

For example, in the manufacturing method provided in at least one embodiment of the present disclosure, the resin matrix comprises epoxy resin, acrylic resin or polyurethane.

For example, in the manufacturing method provided in at least one embodiment of the present disclosure, the conductive dopant comprises metal particles, metal fibers, carbon particles, carbon fibers, or graphene.

### BRIEF DESCRIPTION OF THE DRAWINGS

In order to clearly illustrate the technical solution of the embodiments of the disclosure or the prior art, the drawings of the embodiments or description in the prior art will be briefly described in the following. It is obvious that the described drawings are only related to some embodiments of the disclosure, and those skilled in the art can also obtain other drawings without any inventive work according to the drawings.

FIG. 1 is a schematic structure diagram of an array substrate provided by an embodiment of the present disclosure;

FIG. 2 is a schematic diagram of a sectional structure of the array substrate illustrated in FIG. 1 along the A-B line;

FIG. 3 is a schematic diagram of a sectional structure of a top-gate TFT provided by an embodiment of the present disclosure;

FIG. 4 is a schematic structure diagram of a display panel provided by an embodiment of the present disclosure; and

FIG. 5 is a flow diagram of a method for manufacturing an array substrate provided by an embodiment of the present disclosure.

### DETAILED DESCRIPTION

The technical solutions in the embodiments of the disclosure will be described in a clearly and fully understandable way in connection with the drawings related to the embodiments of the disclosure. It is obvious that the described embodiments are just a part but not all of the embodiments of the disclosure. Based on the embodiments in the disclosure, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “on,” “under,” “right,” “left” and the like are only used to indicate relative position relationship, and when the position of the object which is described is changed, the relative position relationship may be changed accordingly.

Generally, in an LCD panel of an IPS mode, a pixel electrode and a common electrode are made of transparent conductive material or metal material. If the pixel electrode and the common electrode are made of transparent conductive material or metal material, a method of depositing a film is usually adopted. The pixel electrode or the common electrode formed by the method of depositing a film has thin thickness. Thus, after a voltage signal is applied to the pixel electrode and the common electrode, a cambered electric field line is formed between an upper surface of the pixel electrode and an upper surface of the common electrode, and liquid crystal molecules are arranged along the cambered electric field line, as a result, light transmittance of the liquid crystal panel is reduced. Even the thickness (height) of the pixel electrode and the thickness (height) of the common electrode are increased with multiple deposition methods, a problem that a transparent conductive layer or a metal layer tends to be stripped off may be generated due to a weak adhesive force between multiple conductive layers. Moreover, the process is complex and the cost is high.

In the study, the inventors of the present disclosure note that: if the pixel electrode and the common electrode are made of conductive resin material with a certain hardness, both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode. So that the liquid crystal molecules may be arranged uniformly. Thus, switching speed of the liquid crystal molecules is increased, and display response speed of the LCD panel is accelerated. Moreover, the light transmittance of the LCD panel and the display effect of the LCD panel are improved.

At least one embodiment of the present disclosure provides an array substrate and a manufacturing method thereof, a display panel and a display device. The array substrate comprises: a base substrate; a gate line and a data line which are disposed on the base substrate, in which the gate line and the data line are intersected to define a pixel region; and a pixel electrode and a common electrode that are in the pixel region; both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode.

In a case that pixel electrodes and common electrodes with the above mentioned structure are applied to a display panel in an IPS display mode, distributions of parallel electric fields produced by the pixel electrodes and the common electrodes are more uniform after voltages are applied to the pixel electrodes and the common electrodes, it is beneficial to increase the switching speed of the liquid crystals, to improve the light transmittance and to improve the response speed of the display panel. In addition, in a case that the pixel electrodes and the common electrodes with the above mentioned structure are applied to the display panel, at least a portion of spacers arranged between the array substrate and the opposed substrate may be omitted, and the pixel electrodes and the common electrodes may play roles of supporting the opposed substrate, and hence compressive performance of the LCD panel is improved.

At least one embodiment of the present disclosure provides an array substrate. A switching element on the array substrate may be a thin film transistor or other switching elements. For example, the array substrate may be a TFT array substrate. Description will be given below by taking the TFT array substrate as an example.

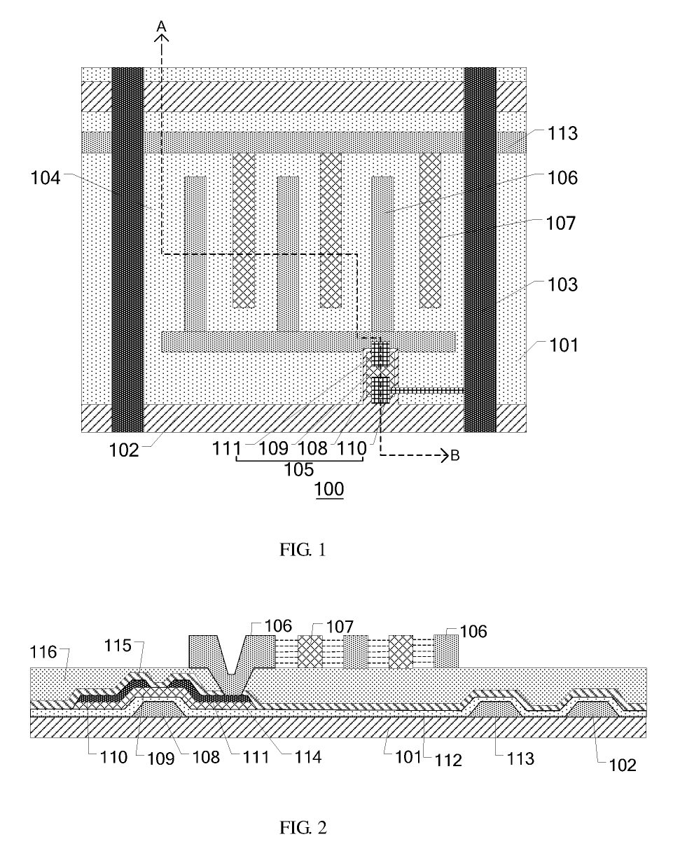

For example, FIG. 1 is a schematic structure diagram of an array substrate provided by an embodiment of the present disclosure, and FIG. 2 is a schematic diagram of a sectional structure of the array substrate illustrated in FIG. 1 along the A-B line. As illustrated in FIGS. 1 and 2, the array substrate 100 comprises: a base substrate 101; gate lines 102 and data lines 103 disposed on the base substrate 101, in which the gate lines 102 and the data lines 103 are intersected to define pixel regions 104; and thin film transistors 105, pixel electrodes 106 and common electrodes 107 are in the pixel regions 104, both the pixel electrodes 106 and the common electrodes 107 are perpendicular to the base substrate 101 and protruded from the base substrate 101, and the pixel electrodes 106 and the common electrodes 107 are opposite to each other; and after voltages are applied to the pixel electrodes 106 and the common electrodes 107, electric fields parallel to the base substrate 101 are generated between surfaces of the pixel electrodes 106 facing the common electrodes 107 and surfaces of the common electrodes 107 facing the pixel electrodes 106, and cambered electric field lines will not be formed on the top of the pixel electrodes and the common electrodes.

For example, both the pixel electrodes 106 and the common electrodes 107 may be manufactured to be very thick (high), and the pixel electrodes 106 and the common electrodes 107 are arranged opposite to each other. As a result, surfaces of the pixel electrodes facing to the common electrodes and surfaces of the common electrodes facing to the pixel electrodes 106 limit a space to accommodate liquid crystals. Moreover, after electrical signals (obtained by energization) are applied to the pixel electrodes and the common electrodes, uniform horizontal electric fields are formed in the space, and the horizontal electric field lines are perpendicular to the surfaces of the pixel electrodes 106 facing the common electrodes 107 and the surfaces of the common electrodes 107 facing the pixel electrodes 106. The electric fields act on the liquid crystals accommodated between the pixel electrodes and the common electrodes to control the arrangement of liquid crystal molecules. Herein, “protruded” refers to that the pixel electrodes and the common electrodes 107 are extended along a direction perpendicular to the base substrate 101, and the thickness (height) of the pixel electrodes 106 and the thickness (height) of the common electrodes 107 are consistent with the thickness (height) of a liquid crystal layer therebetween. The liquid crystal molecules may be uniformly arranged along the parallel electric field lines between the pixel electrodes 106 and the common electrodes 107.

For example, the base substrate 101 is a transparent insulating substrate, the base substrate 101 is made of glass, quartz or other suitable materials.

For example, as illustrated in FIG. 1, two gate lines 102 and two data lines 103 are intersected to define a pixel region 104. FIG. 1 only illustrates two gate lines 102 and two data lines 103. A plurality of gate lines 102 and a plurality of data lines 103 may be disposed on the base substrate 101. The materials applicable to the gate lines 102 and the data lines 103 comprise copper, copper alloy, aluminum, aluminum alloy, molybdenum, molybdenum alloy or other suitable materials. The gate lines 102 comprise a plurality of gate electrodes 108 branched from the gate lines 102, and gate signals are applied to the gate electrodes 108 through the gate lines 102.

For example, as illustrated in FIG. 1, a common electrode line 113 is disposed on the base substrate 101 and the common electrode line 113 is basically parallel to the gate lines 102. FIG. 1 only shows one common electrode line 113. A plurality of common electrode lines 113 may be disposed on the base substrate 101. The materials applicable to the common electrode line 113 comprise copper, copper alloy, aluminum, aluminum alloy, molybdenum, molybdenum alloy, conductive resin or other suitable materials. For example, the common electrode line and the gate lines may be arranged in a same layer or arranged in different layers.

For example, as illustrated in FIG. 1, the TFT 105 comprises: a gate electrode 108 connected to one of the gate lines 102, an active layer 109, a source electrode 110 connected to one of the data lines 103 and in contact with the active layer 109, a drain electrode 111 arranged opposite to the source electrode 110 and in contact with the active layer 109, and a gate insulating layer 112 disposed between the gate electrode 108 and the active layer 109. Moreover, the drain electrode 111 is electrically connected with one of the pixel electrodes 106.

For example, as illustrated in FIG. 2, the gate insulating layer 112 covers the gate lines 102, the gate electrode 108 and the common electrode lines 113. The gate insulating layer 112 is made of silicon oxide or silicon nitride.

For example, the active layer 109 is disposed on the gate insulating layer 112, and the active layer 109 corresponds to the gate electrode 108, and the active layer 109 is made of amorphous silicon (a-Si), metal oxide semiconductor or organic semiconductor, etc.

For example, the source electrode 110 and the drain electrode 111 may be made of copper, copper alloy, aluminum, aluminum alloy, molybdenum, molybdenum alloy or other suitable materials.

For example, a passivation layer 115 covers the data line 103, the active layer 109, the source electrode 110 and the drain electrode 111. The passivation layer 115 comprises a via hole 114 for exposing a portion of the drain electrode 111. The passivation layer 115 is made of silicon oxide, silicon nitride or other suitable materials.

For example, a planarization layer 116 may be disposed on the passivation layer 115. A thickness of the planarization layer 116 is large. The planarization layer 116 is not smooth at the via hole 114, but the surface of the planarization layer at other portions is smooth. For example, the planarization layer 116 is made of inorganic materials such as silicon oxide and silicon nitride or organic materials such as epoxy resin, acrylic resin and polyurethane.

For example, as illustrated in FIG. 2, the pixel electrodes 106 are disposed on the planarization layer 116 and one of the pixel electrodes 106 is electrically connected with the drain electrode 111 through the via hole 114. Thus, data signals (voltages) may be applied to the pixel electrodes 106 through the data lines and the TFTs. The pixel electrodes 106 are made of conductive resin materials. Although FIG. 1 only shows three pixel electrodes 106 in a shape of strip in one pixel region, the array substrate may further comprise more pixel regions, and each pixel regions may comprise more pixel electrodes 106 in a shape of strip.

For example, the common electrodes 107 are arranged on the planarization layer 116 and electrically connected with the common electrode lines 113 through via holes (not illustrated in the FIG. 2). Common voltages are applied to the common electrodes 107 through the common electrode lines 113. The common electrodes 107 are made of conductive resin materials. Although FIG. 1 only shows three common electrodes 107 in a shape of strip in one pixel region, the array substrate may also comprise more pixel regions, each pixel regions may further comprise more common electrodes 107 in a shape of strip.

The pixel electrodes 106 and the common electrodes 107 are in a shape of strip, the pixel electrodes 106 and the common electrodes 107 are arranged opposite to each other, so that uniform horizontal electric fields are formed between the pixel electrodes and the common electrodes.

For example, each pixel regions 104 comprises at least one pixel electrode 106 or at least one common electrode 107. For example, each pixel electrodes 106 is arranged adjacent to the common electrodes 107, and each common electrodes 107 is arranged adjacent to the pixel electrodes 106.

For example, the conductive resin materials comprise a resin matrix and a conductive dopant. After conductive particles are doped into the resin matrix, the resin matrix is modified, so the entire resin matrix has electrical conductivity.

For example, the resin matrix comprises epoxy resin, acrylic resin or polyurethane. For example, the resin matrix may further comprise phenolic resin, alkyd resin, synthetic fatty acid resin, etc.

For example, the conductive dopant comprises metal particles, metal fibers, carbon particles, carbon fibers, or graphene. For example, the metal particles or metal fibers comprise silver nanoparticles or silver fibers, nickel nanoparticles or nickel fibers, etc.; the carbon particles comprise hollow carbon particles, solid carbon balls, core-shell carbon balls and colloidal carbon balls; and the carbon fibers comprise acrylonitrile base carbon fibers and asphalt base carbon fibers. For example, the conductive dopant may further comprise seamless and hollow conductive carbon nanotubes rolled by graphene sheets, and the carbon nanotubes comprise single-walled carbon nanotubes, double-walled carbon nanotubes and multi-walled carbon nanotubes.

For example, the conductive resin materials may have a certain hardness, as illustrated in FIG. 2, the conductive resin materials may satisfy the requirement that the pixel electrodes 106 and the common electrodes 107 are manufactured to have a large thickness (height), namely can satisfy the case that the pixel electrodes 106 and the common electrodes 107 are perpendicular to the base substrate 101 and protruded from the base substrate 101, and electric fields parallel to the base substrate 101 may be generated between the surface of the pixel electrode facing the common electrode and the surface of the common electrode facing the pixel electrode. The resin matrix further has a good light transmittance, so aperture ratio of the thin film transistor array substrate is not reduced.

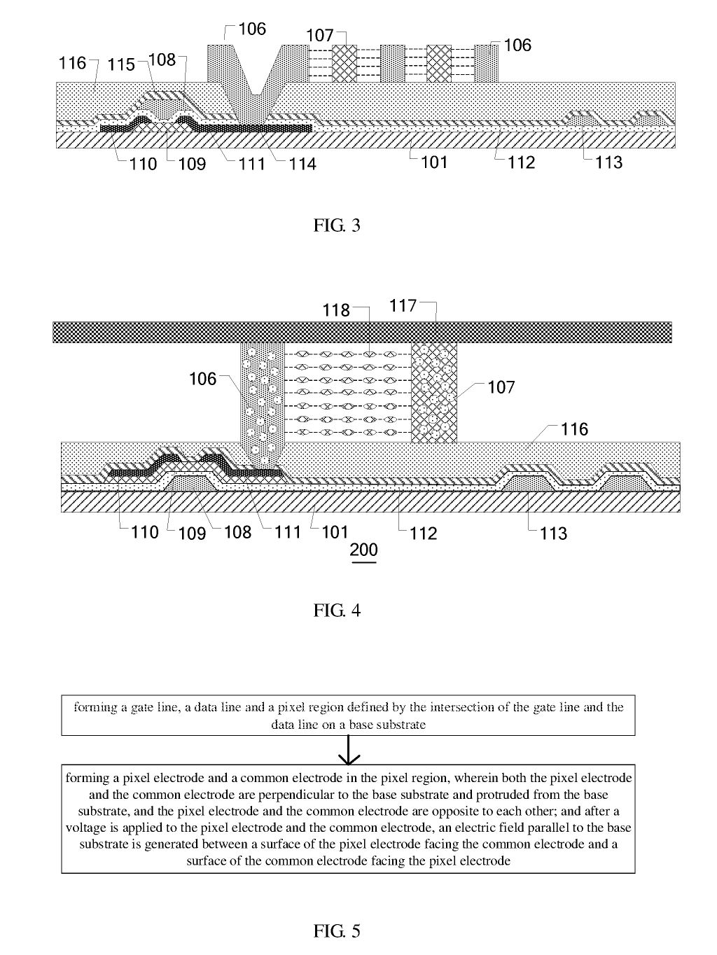

For example, the TFT 105 may be a bottom-gate or a top-gate TFT. Description is given in FIGS. 1 and 2 by taking the bottom-gate TFT as an example. For example, FIG. 3 is a schematic diagram of a sectional structure of a top-gate TFT provided by an embodiment of the present disclosure. A gate electrode 108 is disposed above an active layer 109, a source electrode 110 and a drain electrode 111, and a gate insulating layer 112 is disposed below the gate electrode 108, so as to isolate the gate electrode 108 and the active layer 109. Other structures and materials of each layers are all consistent with the contents described in the bottom-gate TFTs, and detailed descriptions will be omitted here.

At least one embodiment of the present disclosure further provides a display panel. For example, FIG. 4 is a schematic structure diagram of a display panel provided by an embodiment of the present disclosure. For example, as illustrated in FIG. 4, the display panel 200 comprises any one of the TFT array substrate 100 described above, an opposed substrate 117 arranged in parallel to the base substrate 101, and liquid crystal molecules 118 disposed between the array substrate 100 and the opposed substrate 117.

For example, as illustrated in FIG. 4, a thickness (height) of the pixel electrodes and a thickness (height) of the common electrodes in a direction perpendicular to the base substrate 101 is a thickness (height) of the liquid crystal molecules layer 118. Herein, the thickness (height) of the pixel electrodes and the thickness (height) of the common electrodes in the direction perpendicular to the base substrate 101 is a height from the planarization layer 116 to one side of the opposed substrate 117 opposite to the base substrate 101. It should be noted that, the thickness (height) of the pixel electrodes 106 and the thickness (height) of the common electrodes 107 in the direction perpendicular to the base substrate 101 is not the thickness (height) of the liquid crystal molecules layer 118 in strict significance.

For example, as illustrated in FIG. 4, both the pixel electrodes 106 and the common electrodes 107 are perpendicular to the opposed substrate 117 and configured to support the opposed substrate 117. The pixel electrodes 106 and the common electrodes 107 with the above mentioned structure are applied to a display panel in an IPS display mode. After voltages are applied to the pixel electrodes 106 and the common electrodes 107, distributions of horizontal electric fields formed between the pixel electrodes 106 and the common electrodes 107 may be more uniform, so that the liquid crystal molecules 118 can be uniformly arranged between the two electrodes along the direction of electric field lines, and hence the light transmittance is improved. The pixel electrodes 106 and the common electrodes 107 not only have a conductive function but also may at least partially replace spacers disposed between the array substrate 101 and the opposed substrate 117 and play roles of supporting the opposed substrate 117, so that the processing operations are reduced.

For example, the opposed substrate 117 is a CF substrate. Both the pixel electrodes 106 and the common electrodes 107 are perpendicular to the base substrate and configured to support the CF substrate, and the pixel electrodes and the common electrodes may at least partially replace spacers disposed between the array substrate 101 and the CF substrate, so that the processing operations are simplified.

At least one embodiment of the present disclosure further provides a display device, which comprises any one of the above mentioned display panel 200.

For example, the display device may be: a liquid crystal display, an electronic paper, an organic light-emitting diode (short for OLED), or a mobile phone, a tablet computer, a television, a display, a notebook computer, a digital picture frame, a navigation system and any other product or component having a display function.

At least one embodiment of the present disclosure further provides a method for manufacturing an array substrate. For example, FIG. 5 is a flow diagram of a method for manufacturing an array substrate provided by an embodiment of the present disclosure. The method comprises: forming a gate line, a data line and a pixel region defined by the intersection of the gate line and the data line on a base substrate; and forming a pixel electrode and a common electrode in the pixel region, both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode.

For example, both the pixel electrode and the common electrode are manufactured to be very thick (high), and are arranged opposite to each other. Herein, “protruded” refers to that the pixel electrode and the common electrode are extended along a direction perpendicular to the base substrate, and the thickness (height) of the pixel electrode and the thickness (height) of the common electrode are consistent with the thickness (height) of a liquid crystal layer therebetween. The liquid crystal molecules may be uniformly arranged along the horizontal electric field lines between the pixel electrode and the common electrode.

For example, both the pixel electrode and the common electrode are made of conductive resin materials. The conductive resin materials comprise a resin matrix and a conductive dopant.

For example, the pixel electrode and the common electrode which are protruded from the base substrate may be manufactured in a photolithography method. For example, description is given by taking a method for manufacturing a TFT array substrate as an example. First, forming (for example, coating) a conductive resin material layer on the base substrate provided with TFTs, drive circuits such as gate lines and data lines, a passivation layer and the like; second, forming a photoresist layer on the conductive resin material layer, and a photoresist pattern is obtained by exposing and developing the photoresist layer; third, pixel electrode and common electrode are obtained by etching the conductive resin material layer via the photoresist pattern; and finally, removing the remaining photoresist pattern. Or if the conductive resin materials have photosensitive property, the pixel electrode and the common electrode may be obtained by performing exposure and development on the formed conductive resin material layer directly.

The TFTs, drive circuits such as gate lines and data lines, a passivation layer and the like on the base substrate may be obtained in the conventional methods.

For example, the resin matrix comprises epoxy resin, acrylic resin or polyurethane. For example, the resin matrix may further comprise phenolic resin, alkyd resin, synthetic fatty acid resin, etc.

For example, the conductive dopant comprises metal particles, metal fibers, carbon particles, carbon fibers, or graphene. For example, the metal particles or metal fibers comprise silver nanoparticles or silver fibers, nickel nanoparticles or nickel fibers, etc.; the carbon particles comprise hollow carbon particles, solid carbon balls, core-shell carbon balls and colloidal carbon balls; and the carbon fibers comprise acrylonitrile base carbon fibers and asphalt base carbon fibers. For example, the conductive dopant may further comprise seamless and hollow conductive carbon nanotubes rolled by graphene sheets, and the carbon nanotubes comprise single-walled carbon nanotubes, double-walled carbon nanotubes and multi-walled carbon nanotubes.

For example, the conductive resin materials may have a certain hardness, the conductive resin materials may satisfy the requirement that the pixel electrode and the common electrode are manufactured to have a large thickness (height), namely can satisfy the case that the pixel electrode and the common electrode are perpendicular to the base substrate 101 and protruded from the base substrate 101. The resin matrix further has a good light transmittance, so the aperture ratio of the thin film transistor array substrate is not reduced.

Embodiments of the present disclosure provide a TFT array substrate and a manufacturing method thereof, a display panel and a display device, which have at least one of the following advantages:

(1) In a case that pixel electrodes and common electrodes with the above mentioned structure are applied to a display panel with the IPS display mode, distributions of parallel electric fields produced by the pixel electrodes and the common electrodes are more uniform after voltages are applied to the pixel electrodes and the common electrodes, so that the light transmittance is improved;

(2) The uniform parallel electric fields formed after electrifying can improve the switching speed of the liquid crystal molecules, and hence improve the response speed of the LCD panel.

(3) In a case that the pixel electrodes and the common electrodes with the above mentioned structure are applied to the display panel, the pixel electrodes and the common electrodes may at least partially replace the spacers disposed between the array substrate and the opposed substrate, and have the function of supporting the opposed substrate.

There are also some points to be illustrated in the present disclosure:

(1) Drawings of the embodiments of the present disclosure only refer to structures related with the embodiments of the present disclosure, and other structures may refer to general design.

(2) In order to make it clear, in the drawings for illustrating the embodiment of the present disclosure, various components are magnified or reduced, that is, those drawings are not drawn according to actual proportion.

(3) In case of no conflict, the embodiments of the present disclosure and the features of the embodiments may be combined with each other to form new embodiments.

What are described above is related to the illustrative embodiments of the disclosure only and not limitative to the scope of the disclosure; the scopes of the disclosure are defined by the accompanying claims.

The present application claims priority of the Chinese Patent Application No. 201610378261.6, filed on May 31, 2016, the disclosure of which are incorporated herein by its reference in its entirety as part of the present application.

1. An array substrate, comprising:
a base substrate;
a gate line and a data line which are disposed on the base substrate, wherein the gate line and the data line are intersected to define a pixel region; and
a pixel electrode and a common electrode that are in the pixel region;
wherein both the pixel electrode and the common electrode are perpendicular to the base substrate and protruded from the base substrate, and the pixel electrode and the common electrode are opposite to each other; and after a voltage is applied to the pixel electrode and the common electrode, an electric field parallel to the base substrate is generated between a surface of the pixel electrode facing the common electrode and a surface of the common electrode facing the pixel electrode.

2. The array substrate according to claim 1, wherein both the pixel electrode and the common electrode are made of a conductive resin material.

3. The array substrate according to claim 2, wherein the conductive resin material comprises a resin matrix and a conductive dopant.

4. (canceled)

5. The array substrate according to claim 3, wherein the conductive dopant comprises metal particles, metal fibers, carbon particles, carbon fibers, or graphene.

6. The array substrate according to claim 1, wherein the array substrate further comprises a thin film transistor (TFT), and
the TFT comprises: a gate electrode connected to the gate line, an active layer, a source electrode connected to the data line and in contact with the active layer, a drain electrode arranged opposite to the source electrode and in contact with the active layer, and a gate insulating layer disposed between the gate electrode and the active layer, wherein the drain electrode is electrically connected with the pixel electrode.

7. The array substrate according to claim 6, wherein a passivation layer is provided on the TFT and a via hole penetrates the passivation layer.

8. The array substrate according to claim 7, wherein the pixel electrode is electrically connected with the drain electrode through the via hole.

9. The array substrate according to claim 6, wherein the TFT is a bottom-gate TFT or a top-gate TFT.

10. The array substrate according to claim 1, wherein the pixel electrode and the common electrode are in a shape of strip, and the pixel electrode and the common electrode are arranged opposite to each other.

11. The array substrate according to claim 10, wherein the pixel region comprises at least two pixel electrodes and at east two common electrodes.

12. The array substrate according to claim 11, further comprising common electrode lines, wherein the at least two common electrodes are electrically connected with the common electrode lines.

13. A display panel, comprising:
the array substrate according to claim 1,
an opposed substrate arranged in parallel to the base substrate, and liquid crystal molecules disposed between the array substrate and the

14. The display panel according to claim 13, wherein both a thickness of the pixel electrode and a thickness of the common electrode in a direction perpendicular to the base substrate are a thickness of the liquid crystal molecules layer.

15. The display panel according to claim 13, wherein both the pixel electrode and the common electrode are perpendicular to the opposed substrate and configured to support the opposed substrate.

16. The display panel according to claim 15, wherein the opposed substrate is a color filter (CF) substrate.

17. A display device, comprising the display panel according to claim 13.

18. A method for manufacturing an array substrate, comprising:
forming a gate line, a data line and a pixel region defined by the intersection of the gate line and the data line on a base substrate; and
forming a pixel electrode and a common electrode in the pixel region,
wherein both the pixel electrode and the common electrode are perpendicular to the base substrate and protruded from the base substrate, and the pixel electrode and the common electrode are opposite to each other, an electric field parallel to the base substrate is generated between a surface of the pixei electrode facing the common electrode and a surface of the common electrode facing the pixel electrode.

19. The manufacturing method according to claim 18, wherein both the pixel electrode and the common electrode are made of a conductive resin material.

20. The manufacturing method according to claim 19, wherein the conductive resin material comprises a resin matrix and a conductive dopant.

21. (canceled)

22. The manufacturing method according to claim 20, wherein the conductive dopant comprises metal particles, metal fibers, carbon particles, carbon fibers, or graphene.
